(19) United States
(12) Patent Application Publication
(10) Pub. No.: US 2013/0010420 A1
(43) Pub. Date: Jan. 10, 2013

(54) BRACKET FOR EXPANSION CARD AND ELECTRONIC DEVICE HAVING THE SAME

(75) Inventor: ZI-XUAN ZHANG, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen (TW)

(21) Appl. No.: 13/267,905

(22) Filed: Oct. 7, 2011

(30) Foreign Application Priority Data
Jul. 8, 2011 (CN) 201110190980.2

(51) Int. Cl. G06F 1/16; H05K 7/14

(52) U.S. Cl. 361/679.32; 248/225.11; 248/224.8; 248/222.14

(57) ABSTRACT

An electronic device includes an enclosure, an expansion card installed inside the enclosure, and a bracket. The enclosure includes a sidewall defining a through slot, and a supporting plate extending outwards from an upper portion of the sidewall. The bracket includes a fixing plate, and a stop plate. The fixing plate is supported on and fixed to a top of the supporting plate. The stop plate extends down from the fixing plate to fix an end of the expansion card. The stop plate engages with an inner side of the sidewall and covers the through slot. A number of vents is defined in the stop plate in communication with the through slot so that hot air in the enclosure may be dissipated by a cooling airflow through the vents and the through slot.

### BACKGROUND

1. Technical Field

The present disclosure relates to a bracket for fixing an expansion card, and an electronic device having the bracket.

2. Description of Related Art

An enclosure of an electronic device generally defines a plurality of openings. To assemble an expansion card, a bracket is fixed to an end of the expansion card, and then the bracket is fixed to the enclosure and covers the opening, thereby fixing the expansion card to the electronic device. However, the expansion card and other electronic components installed in the electronic device will produce a lot of heat, and the bracket may impede airflow meant to carry away the heat.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of an electronic device, wherein the electronic device includes an enclosure, an expansion card, and a bracket.

FIG. 2 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

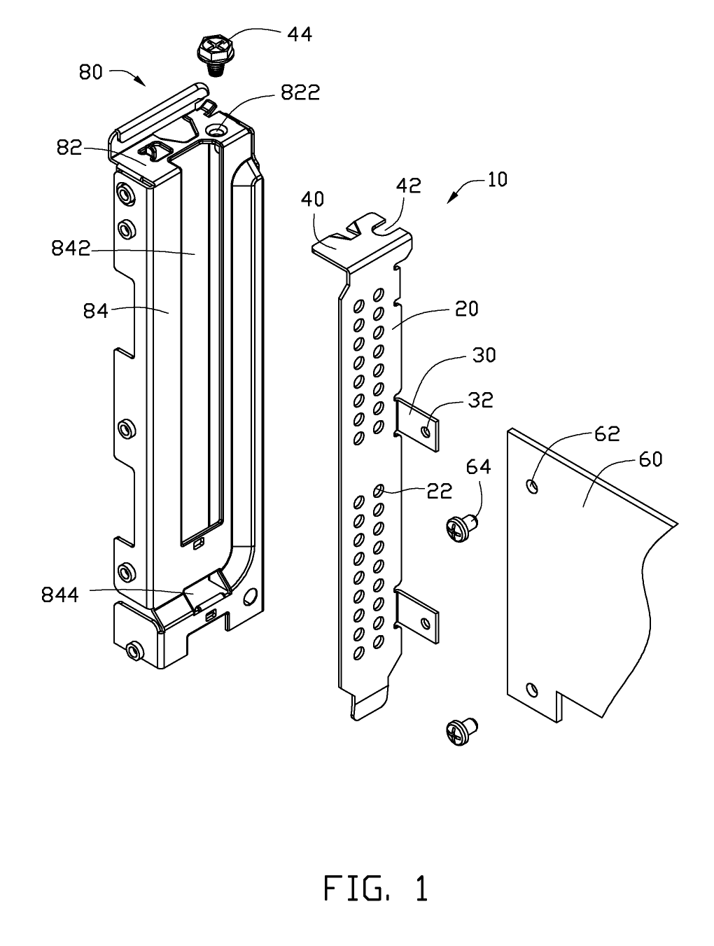

Referring to FIG. 1, an exemplary embodiment of an electronic device includes an enclosure 80, bracket 10, and an expansion card 60.

The bracket 10 is substantially L-shaped, and includes a stop plate 20, two tabs 30 perpendicularly extending from a side of the stop plate, and a fixing plate 40 perpendicularly extending away from the tabs 30 from the top of the stop plate 20. A plurality of vents 22 is defined in the stop plate 20. A mounting hole 32 is defined in each tab 30. A cutout 42 is defined in an end of the fixing plate 40.

Two through holes 62 are defined in an end of the expansion card 60.

The enclosure 80 includes a sidewall 84, and a supporting plate 82 perpendicularly extending outwards from an upper portion of the sidewall 84. A through slot 842 is defined in the sidewall 84 from top to bottom, and a latching slot 844 is defined in the inner side of the sidewall 84 below the through slot 842. A threaded hole 822 is defined in the supporting plate 82 adjacent to the through slot 842.

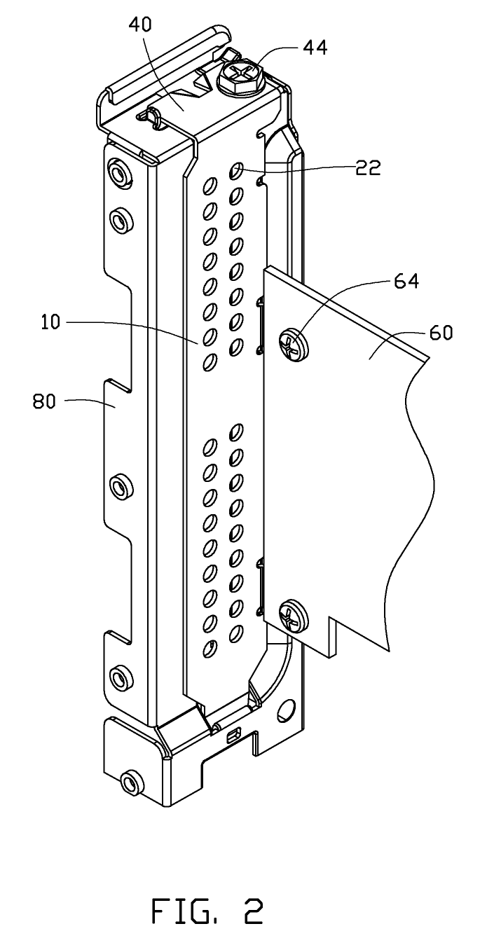

Referring to FIG. 2, in assembly, two fasteners 64 are respectively extended through the through holes 62 and engage in the corresponding mounting holes 32, to fix the expansion card 60 to the bracket 10. The bottom of the stop plate 20 engages in the latching slot 844 of the sidewall 84. The bracket 10 is rotated towards the sidewall 84, until the fixing plate 40 engages with the top surface of the supporting plate 82, and the stop plate 20 engages with the inner side of the sidewall 84. The cutout 42 aligns with the threaded hole 822. The stop plate 20 covers the through slot 842, with the vents 22 communicating with the through slot 842. A screw 44 is extended through the cutout 42 and engages in the threaded hole 822. Thereby, the bracket 10 and the expansion card 60 are fixed inside the enclosure 80, the electronic device is assembled.

In use, some hot air in the enclosure 80 can be dissipated out through the vents 22 and the through slot 842, thus the bracket 10 can enhance heat dissipation efficiency.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A bracket for fixing an expansion card inside an enclosure, the enclosure comprising a sidewall defining a through slot, and a supporting plate extending outwards from an upper portion of the sidewall, the bracket comprising:
a fixing plate for being supported on and fixed to a top of the supporting plate; and
a stop plate extending down from the fixing plate to fix an end of the expansion card, the stop plate being configured for engaging with an inner side of the sidewall and covering the through slot, a plurality of vents defined in the stop plate in communication with the through slot.

2. The bracket of claim 1, wherein two tabs perpendicularly extend from a side of the stop plate and away from the sidewall of the enclosure, a mounting hole is defined in each tab, two fasteners are extended through the expansion card and engage in the mounting holes, to fix the expansion card to the bracket.

3. The bracket of claim 1, wherein a cutout is defined in an end of the fixing plate of the bracket, a screw is extended through the cutout and engages with the supporting plate, to fix the fixing plate to the supporting plate.

4. An electronic device, comprising:
an enclosure comprising a sidewall defining a through slot, and a supporting plate extending outwards from an upper portion of the sidewall;
an expansion card installed inside the enclosure; and
a bracket comprising a fixing plate supported on and fixed to a top of the supporting plate, and a stop plate extending down from the fixing plate to fix an end of the expansion card, the stop plate engaging with an inner side of the sidewall and covering the through slot, a plurality of vents defined in the stop plate in communication with the through slot.

5. The electronic device of claim 4, wherein two tabs perpendicularly extend from a side of the stop plate and away from the sidewall of the enclosure, a mounting hole is defined in each tab, two fasteners are extended through the expansion card and engage in the mounting holes, to fix the expansion card to the bracket.

6. The electronic device of claim 4, wherein a threaded hole is defined in the supporting plate adjacent to the through slot, a cutout is defined in an end of the fixing plate of the bracket, a screw is extended through the cutout and engages in the threaded hole, to fix the fixing plate to the supporting plate.
